(19) United States
(12) Patent Application Publication
(10) Pub. No.: US 2026/0234469 A1
(43) Pub. Date: Aug. 13, 2026

(54) METHOD OF PRODUCING PEROVSKITE SEMICONDUCTOR FILM

(71) Applicant: NGK INSULATORS, LTD., Nagoya-shi (JP)

(72) Inventors: Atsushi WAKAMIYA, Uji-shi (JP); Tomoya NAKAMURA, Maibara-shi (JP); Noboru OHASHI, Uji-shi (JP); Yoshio KONDO, Nagoya-shi (JP); Yoshimasa OMIYA, Nagoya-shi (JP)

(21) Appl. No.: 19/632,787

(22) Filed: Mar. 30, 2026

Related U.S. Application Data
(63) Continuation of application No. PCT/JP2023/036364, filed on Oct. 5, 2023.

(51) Int. Cl. C09K 11/06; C09K 111/00; H10K 71/15; H10K 85/50

(52) U.S. Cl. CPC C09K 11/06; H10K 71/15; H10K 85/50; C09K 2111/00; C09K 2211/181

(57) ABSTRACT

A method of producing a perovskite semiconductor film includes the steps of: forming a coating film from a raw material solution, which is obtained by dissolving a perovskite compound in a good solvent, under a predetermined temperature; and dropping a poor solvent onto the coating film when the supersaturation degree S of the coating film satisfies the following formula (1) and the content ratio C of the good solvent in the coating film satisfies the following formula (2):

Sₘₐₓ×0.80<S (1)

in the formula (1), Sₘₐₓ represents the maximum supersaturation degree of the coating film that is achievable without dropping the poor solvent onto the coating film at the predetermined temperature; and

Cₛ×0.15≤C (2)

in the formula (2), Cₛ represents the content ratio of the good solvent in the raw material solution.

### CROSS-REFERENCE TO RELATED APPLICATIONS

This application is a continuation under 35 U.S.C. 120 of International Application PCT/JP2023/036364 having the International Filing Date of Oct. 5, 2023. The identified application is fully incorporated herein by reference.

### BACKGROUND OF THE INVENTION

### 1. Field of the Invention

The present disclosure relates to a method of producing a perovskite semiconductor film.

### 2. Description of the Related Art

In recent years, the development of a photoelectric conversion device using a perovskite semiconductor material has been attracting attention. Although the perovskite semiconductor material is an inorganic material, the application of a solution of the perovskite semiconductor material enables the production of a perovskite semiconductor film. For example, there is a proposal of a method of producing a perovskite layer, the method including: applying a solution containing a Sn-based perovskite compound to a substrate to form a coating film; then applying a poor solvent to the coating film; and subjecting the coating film to annealing treatment (see, for example, Patent Literature 1).

### CITATION LIST

### Patent Literature

[PTL 1] WO 2019/182058 A1

### SUMMARY OF THE INVENTION

However, in the method of producing a perovskite layer described in Patent Literature 1, it is difficult to stably produce a perovskite semiconductor film having excellent denseness, and when the perovskite semiconductor film is applied to a photoelectric conversion device, the photoelectric conversion performance of the device may become insufficient.

A primary object of the present disclosure is to provide a method of producing a perovskite semiconductor film by which a perovskite semiconductor film having excellent denseness can be stably produced.
[1] A method of producing a perovskite semiconductor film according to one embodiment of the present disclosure includes the steps of: forming a coating film from a raw material solution, which is obtained by dissolving a perovskite compound in a good solvent, under a predetermined temperature; and dropping a poor solvent onto the coating film when a supersaturation degree S of the coating film satisfies the following formula (1) and a content ratio C of the good solvent in the coating film satisfies the following formula (2):

$${S}_{max} \times 0.8 < S \qquad ( 1 )$$

in the formula (1), Sₘₐₓ represents a maximum supersaturation degree of the coating film that is achievable without dropping the poor solvent onto the above-mentioned coating film at the predetermined temperature; and

$${C}_{s} \times 0.15 \leq C \qquad ( 2 )$$

in the formula (2), Cₛ represents a content ratio of the above-mentioned good solvent in the above-mentioned raw material solution.
[2] In the method of producing a perovskite semiconductor film according to the above-mentioned item [1], the poor solvent may be dropped onto the above-mentioned coating film when the supersaturation degree S of the above-mentioned coating film satisfies the following formula (3):

$${S}_{max} \times 0.9 \leq S \leq {S}_{max} \times 0.98 \qquad ( 3 )$$

in the formula (3), Sₘₐₓ represents the maximum supersaturation degree of the coating film that is achievable without dropping the poor solvent onto the above-mentioned coating film at the predetermined temperature.
[3] In the method of producing a perovskite semiconductor film according to the above-mentioned item [1] or [2], the poor solvent may be dropped onto the above-mentioned coating film when the content ratio C of the above-mentioned good solvent in the above-mentioned coating film satisfies the following formula (4):

$${C}_{s} \times 0.18 \leq C \leq {C}_{s} \times 0.6 \qquad ( 4 )$$

in the formula (4), Cₛ represents the content ratio of the above-mentioned good solvent in the above-mentioned raw material solution.
[4] In the method of producing a perovskite semiconductor film according to any one of the above-mentioned items [1] to [3], the above-mentioned perovskite compound may include a compound represented by the following general formula (I):

ABX₃ (I)

in the general formula (I), A represents an organic ammonium and/or an alkali metal cation, B represents a divalent metal cation, and X represents a halide and/or an anion source.
[5] In the method of producing a perovskite semiconductor film according to any one of the above-mentioned items [1] to [4], the above-mentioned good solvent may include an aprotic polar solvent.
[6] In the method of producing a perovskite semiconductor film according to any one of the above-mentioned items [1] to [5], the above-mentioned poor solvent may include an aromatic hydrocarbon.

According to the embodiments of the present disclosure, the perovskite semiconductor film having excellent denseness can be stably produced.

### BRIEF DESCRIPTION OF THE DRAWINGS

FIG. 1 is a schematic sectional view for describing a method of producing a perovskite semiconductor film according to one embodiment of the present disclosure.

FIG. 2 is a schematic sectional view of a photoelectric conversion device including the perovskite semiconductor film of FIG. 1.

### DESCRIPTION OF THE EMBODIMENTS

Embodiments of the present disclosure are described below with reference to the drawings. However, the present disclosure is not limited to those embodiments. In addition, for clearer illustration, some widths, thicknesses, shapes, and the like of respective portions may be schematically illustrated in the drawings in comparison to the embodiments. However, each of the widths, the thicknesses, the shapes, and the like is merely an example, and does not limit the understanding of the present disclosure.

A. Outline of Method of producing

### Semiconductor Film

### Perovskite

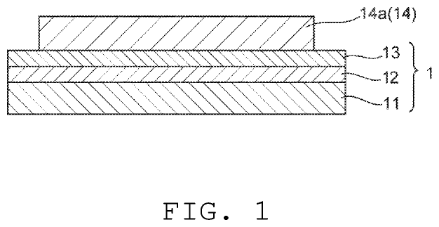

FIG. 1 is a schematic sectional view for describing a method of producing a perovskite semiconductor film according to one embodiment of the present disclosure.

The method of producing a perovskite semiconductor film according to one embodiment of the present disclosure includes: a step of forming a coating film from a raw material solution, which is obtained by dissolving a perovskite compound in a good solvent, under a predetermined temperature (coating film-forming step); and a step of dropping a poor solvent onto the coating film when the supersaturation degree S of the coating film satisfies the following formula (1) and the content ratio C of the good solvent in the coating film satisfies the following formula (2) (poor solvent-dropping step):

$${S}_{max} \times 0.8 < S \qquad ( 1 )$$

in the formula (1), Sₘₐₓ represents the maximum supersaturation degree of the coating film that is achievable without dropping the poor solvent onto the coating film at the predetermined temperature; and

$${C}_{s} \times 0.15 \leq C \qquad ( 2 )$$

in the formula (2), Cₛ represents the content ratio of the good solvent in the raw material solution.

The inventors have discovered that the sizes and precipitation rate of the crystal nuclei of the perovskite compound precipitated when the poor solvent is dropped onto the coating film affect the denseness of the perovskite semiconductor film, and consequently affect the performance of the perovskite semiconductor film. In view of the foregoing, the inventors have made intensive investigations on an improvement in denseness of the perovskite semiconductor film, and as a result, have found that the denseness of the perovskite semiconductor film is improved by precipitating the microcrystal nuclei of the perovskite compound at a predetermined rate or higher. More specifically, in the case where the poor solvent is dropped onto the coating film when the supersaturation degree S of the coating film satisfies the formula (1) and the content ratio C of the good solvent in the coating film satisfies the formula (2), the microcrystal nuclei of the perovskite compound can be precipitated at the predetermined rate or higher, and as a result, the denseness of the perovskite semiconductor film can be remarkably improved. Accordingly, a perovskite semiconductor film suitable for a photoelectric conversion device can be stably produced.

In the coating film-forming step, the good solvent in the coating film may volatilize. Accordingly, the supersaturation degree S of the perovskite compound in the coating film may increase over time, and the content ratio C of the good solvent in the coating film may reduce over time. The respective transitions of the supersaturation degree and the content ratio of the good solvent in such coating film are calculated in advance by, for example, any appropriate computer simulation.

In one embodiment, in the poor solvent-dropping step, the poor solvent is dropped onto the coating film when the supersaturation degree S of the coating film satisfies the following formula (3):

$${S}_{max} \times 0.9 \leq S \leq {S}_{max} \times 0.98 \qquad ( 3 )$$

in the formula (3), Sₘₐₓ represents the maximum supersaturation degree of the coating film that is achievable without dropping the poor solvent onto the coating film at the predetermined temperature.

According to such method, the precipitation rate of the microcrystal nuclei of the perovskite compound in the poor solvent-dropping step can be stably improved, and as a result, the denseness of the perovskite semiconductor film can be stably improved.

When the maximum supersaturation degree Sₘₐₓ of the coating film is defined as 100%, the ratio of the supersaturation degree S of the coating film at the time of the dropping of the poor solvent (=S/Sₘₐₓ×100) is, for example, 80% or more, preferably 85% or more, more preferably 90% or more, still more preferably 93% or more. Meanwhile, the ratio (S/Sₘₐₓ×100) is, for example, 100% or less, preferably 98% or less. When the ratio (S/Sₘₐₓ×100) falls within such ranges, the denseness of the perovskite semiconductor film can be more stably improved.

In one embodiment, in the poor solvent-dropping step, the poor solvent is dropped onto the coating film when the content ratio C of the good solvent in the coating film satisfies the following formula (4):

$${C}_{s} \times 0.18 \leq C \leq {C}_{s} \times 0.6 \qquad ( 4 )$$

in the formula (4), Cₛ represents the content ratio of the good solvent in the raw material solution.

According to such method, the precipitation rate of the microcrystal nuclei of the perovskite compound in the poor solvent-dropping step can be further improved, and as a result, the denseness of the perovskite semiconductor film can be further improved.

When the content ratio Cₛ of the good solvent in the raw material solution is defined as 100%, the ratio of the content ratio C of the good solvent in the coating film at the time of the dropping of the poor solvent (=C/Cₛ×100) is, for example, 15% or more, preferably 18% or more, more preferably 20% or more, still more preferably 30% or more, particularly preferably 35% or more. Meanwhile, the ratio (C/Cₛ×100) is, for example, 80% or less, preferably 60% or less, more preferably 50% or less, still more preferably 45% or less. When the ratio (C/Cₛ×100) falls within such ranges, the denseness of the perovskite semiconductor film can be even further improved.

The average primary particle diameter of the microcrystal nuclei of the perovskite compound precipitated in the poor solvent-dropping step may be, for example, from about several nanometers to about 20 nm. However, it is difficult to actually measure the diameter.

In addition, the precipitation rate (maximum value) of the microcrystal nuclei of the perovskite compound in the poor solvent-dropping step is, for example, from about 0.03 kg/m²s to about 0.15 kg/m²s, and as the average primary particle diameter becomes smaller, the precipitation rate (number) of the microcrystal nuclei per unit time may become larger. However, it is also difficult to accurately measure the precipitation rate.

In one embodiment, in the poor solvent-dropping step, a precursor film containing the microcrystal nuclei of the perovskite compound is prepared from the above-mentioned coating film. Accordingly, the method of producing a perovskite semiconductor film further includes a firing step as required. In the firing step, the precursor film prepared in the poor solvent-dropping step is fired. Thus, a perovskite semiconductor film having excellent denseness can be even more stably produced.

In the following, details about the respective steps of the method of producing a perovskite semiconductor film are described.

### B. Coating Film-forming Step

As illustrated in FIG. 1, in one embodiment, a raw material solution is prepared by dissolving a perovskite compound in a good solvent, and the solution is applied to a base material 1 to form a coating film 14a on the base material 1.

### B-1. Perovskite Compound

The raw material solution is prepared by adding the perovskite compound to the good solvent, and stirring and/or heating the mixture as required.

The perovskite compound typically includes a compound represented by the following general formula (I):

ABX₃ (I)

in the general formula (I), A represents an organic ammonium and/or an alkali metal cation, B represents a divalent metal cation, and X represents a halide and/or an anion source.

Examples of the organic ammonium represented by A in the general formula (I) include: alkylammoniums, such as methylammonium, ethylammonium, n-butylammonium, di-n-butylammonium, di-n-hexylammonium, trimethylammonium, triethylammonium, methyl-n-hexylammonium, methyldiethylammonium, tri-n-hexylammonium, and tri-t-butylammonium; imidazolium; aziridinium; formamidinium; guanidinium; anilinium; pyridinium; 4-t-butylpyridinium; and phenethylammonium.

A typical example of the alkali metal cation represented by A in the general formula (I) is a monovalent alkali metal cation. Examples of the alkali metal include cesium, potassium, and rubidium.

Such As may be used alone or in combination thereof. Of such As, a combination of an organic ammonium and an alkali metal cation is preferred, a combination of an alkylammonium, formamidinium, and an alkali metal cation is more preferred, and a combination of methylammonium (MA⁺), formamidinium (FA⁺), and a cesium cation (Cs⁺) is still more preferred.

When A in the general formula (ABX 3) represents a combination of an alkylammonium(methylammonium), formamidinium, and an alkali metal cation (cesium cation), the molar ratio of the alkylammonium with respect to 1 mol of the alkali metal cation is, for example, from 1 to 5, and the molar ratio of the formamidinium with respect to 1 mol of the alkali metal cation is, for example, from 14 to 18.

An example of the divalent metal cation represented by B in the general formula (I) is a cation of an element belonging to Group XIV (metal element classified into Group XIV in the periodic table defined by IUPAC in 2019), such as lead or tin.

Such Bs may be used alone or in combination thereof. In addition, B may be mixed with a small amount of a trivalent cation, such as an indium or antimony ion, in addition to the above-mentioned divalent metal cation. Of those Bs, a cation of an element belonging to Group XIV is preferred, and a cation of lead (Pb) is more preferred.

X in the general formula (I) preferably represents, for example, a halide. Examples of the halide include a chloride ion, a bromide ion, and iodide ion. Such Xs may be used alone or in combination thereof. Of those Xs, a combination of a bromide ion (Br—) and an iodide ion (I—) is more preferred.

Preferred examples of the perovskite compound represented by the general formula (I) include: a perovskite compound having the composition of Cs_{0.05}FA_{0.80}MA_{0.15}PbI_{2.68}Br_{0.32}; and a perovskite compound having the composition of CS_{0.05}FA_{0.80}MA_{0.15}Pb_{12.75}Br_{0.25}.

### B-2. Good Solvent

The good solvent is capable of dissolving the perovskite compound at normal temperature (25° C.). Any appropriate organic solvent may be adopted as the good solvent. Examples of the good solvent include an aprotic polar solvent, an ester-based solvent, a ketone, a heterocyclic aromatic compound, and an amine. The good solvents may be used alone or in combination thereof.

Of the good solvents, an aprotic polar solvent is preferred. When the good solvent includes the aprotic polar solvent, the perovskite compound can be smoothly dissolved in the good solvent, and hence a solution of the perovskite compound can be smoothly prepared.

Specific examples of the aprotic polar solvent include N-methyl-2-pyrrolidone (NMP), dimethylformamide (DMF), dimethylacetamide (DMA), and dimethyl sulfoxide (DMSO). The aprotic polar solvents may be used alone or in combination thereof.

The boiling point of the good solvent is, for example, from 30° C. to 250° C., preferably from 100° C. to 200° C.

The solubility of the perovskite compound in the good solvent at 25° C. is, for example, from about 1 molar (M) to about 2 M.

The content ratio of the perovskite compound in the raw material solution is, for example, from about 0.05 to about 0.15 on a solute molar ratio basis. Conversely, the content ratio Cₛ of the good solvent in the raw material solution is from about 0.85 to about 0.95.

### B-3. Base Material

The base material 1 is not particularly limited as long as the base material 1 is applicable to the production of a perovskite semiconductor film. The base material 1 may be formed from a single base material, or may be formed from a laminated substrate in which two or more layers are laminated. In the illustrated example, the base material 1 is formed as a laminated substrate including a base material body 11 and a thin film to be arranged on the base material body 11.

Examples of a material for the base material body 11 include glass, ceramics, and a resin material.

Examples of the ceramics include aluminum oxide (Al₂O₃), silicon oxide (SiO₂), silicon nitride (Si₃N₄), and silicon oxynitride (Si₄O₅N₃).

Examples of the resin material include: polyolefins, such as polyethylene and polypropylene; polyesters, such as polyethylene terephthalate and polyethylene naphthalate; ionomers; polyvinyl chloride; polyvinylidene chloride; polyvinyl alcohol; polycarbonate; polystyrene; polyacrylonitrile; an ethylene-vinyl acetate copolymer; an ethylene-vinyl alcohol copolymer; an ethylene-methacrylic acid copolymer; and polyamide.

Materials for the base material 1 may be used alone or in combination thereof. Of the materials for the base material 1, glass is preferred.

Examples of the thin film to be arranged on the base material body 11 include a semiconductor film, a conductor film, and an insulator film. The thin film may be a single layer, or may be a laminate of two or more layers.

In one embodiment, a plurality of conductor films are laminated on the surface of the base material body 11. Examples of the conductor film include a transparent electrode film, an electron-transporting layer, and a hole-transporting layer. In the illustrated example, a transparent electrode film 12 and an electron-transporting layer 13 serving as conductor films are laminated on the surface of the base material body 11.

The transparent electrode film 12 has a function of taking charge out of a perovskite semiconductor film 14. The transparent electrode film 12 is directly arranged on the base material 1. The transparent electrode film 12 may be arranged on the entirety of the surface of the base material 1, or may be arranged only on part of the surface of the base material 1. In the illustrated example, the transparent electrode film 12 is arranged on the entirety of the surface of the base material 1.

Examples of a material for the transparent electrode film 12 include carbon, a conductive metal oxide, and a conductive polymer.

Examples of the carbon include carbon black, a carbon nanotube, and graphene.

Examples of the conductive metal oxide include tin-doped indium oxide (ITO), impurity-doped indium oxide (In₂O₃), impurity-doped zinc oxide (ZnO), and fluorine-doped tin dioxide (FTO).

Examples of the conductive polymer include poly(3, 4-ethylenedioxythiophene) polystyrene sulfonate (PEDOT: PSS), polyaniline, and polyacetylene.

The materials for the transparent electrode film 12 may be used alone or in combination thereof. Of the materials for the transparent electrode film 12, the conductive metal oxide is preferred, and tin-doped indium oxide (ITO) is more preferred.

The thickness of the transparent electrode film 12 is adjusted in any appropriate manner.

The transparent electrode film 12 may be formed from a single layer, or may be formed by laminating two or more layers.

The electron-transporting layer 13 has the following functions: the layer increases the active surface area of the perovskite semiconductor film 14 to improve its photoelectric conversion efficiency; and the layer facilitates the collection of an electron by the transparent electrode film 12. The electron-transporting layer 13 is positioned on the opposite side of the base material body 11 with respect to the transparent electrode film 12. In the illustrated example, the electron-transporting layer 13 is directly arranged on the transparent electrode film 12. The electron-transporting layer 13 may be arranged on the entirety of the surface of the transparent electrode film 12, or may be arranged only on part of the surface of the transparent electrode film 12. In the illustrated example, the electron-transporting layer 13 is arranged on the entirety of the surface of the transparent electrode film 12.

The electron-transporting layer 13 typically includes an n-type semiconductor, and preferably includes an n-type metal oxide semiconductor.

Examples of the metal oxide include titanium oxide (TiO₂) (including mesoporous TiO₂), tin oxide (SnO₂), and zinc oxide (ZnO).

The metal oxides may be used alone or in combination thereof. Of the metal oxides, tin oxide (SnO₂) is preferred.

The thickness of the electron-transporting layer 13 is not particularly limited, and is, for example, from 1 nm to 300 nm, preferably from 1 nm to 100 nm.

The electron-transporting layer 13 may be formed from a single layer, or may be formed by laminating two or more layers.

### B-4. Application Method

Any appropriate method is adopted as a method of applying the raw material solution. Examples of the method of applying the raw material solution include a spin coating method, an inkjet method, a gravure method, and a slot die method.

In one embodiment, the raw material solution is applied onto the base material 1 by a spin coating method. In the illustrated example, the raw material solution is applied onto the electron-transporting layer 13 by the spin coating method. More specifically, the base material 1 is arranged on a stage (not shown) included in any appropriate spin coater, and the raw material solution is supplied onto the base material 1, followed by the rotation of the stage. Thus, the base material 1 is rotated, and the raw material solution is spread by a centrifugal force to form the coating film 14a having a predetermined thickness.

An environmental temperature in the coating film-forming step is, for example, from 5° C. to 40° C.

### C. Poor Solvent-Dropping Step

The coating film 14a to be formed in the coating film-forming step contains the good solvent and the perovskite compound. Under the above-mentioned environmental temperature, the good solvent in the coating film 14a can volatilize. As a result, in the coating film 14a, the supersaturation degree S increases over time, and the content ratio C of the good solvent reduces over time.

Thus, the coating film 14a reaches a state in which the supersaturation degree S satisfies the formula (1) and the content ratio C of the good solvent satisfies the formula (2). After that, the poor solvent is dropped onto the coating film 14a in the state in which the supersaturation degree S satisfies the formula (1) and the content ratio C of the good solvent satisfies the formula (2).

### C-1. Poor Solvent

The poor solvent dissolves the perovskite compound less easily than the above-mentioned good solvent at normal temperature (25° C.). Examples of the poor solvent include an aromatic hydrocarbon, a halogenated aromatic hydrocarbon, a halogenated aliphatic hydrocarbon, an ether, an alcohol, and a nitrile. The poor solvents may be used alone or in combination thereof.

Of the poor solvents, an aromatic hydrocarbon and a halogenated aromatic hydrocarbon are preferred. When the poor solvent includes an aromatic hydrocarbon and/or a halogenated aromatic hydrocarbon, the microcrystal nuclei of the perovskite compound can be suitably precipitated at the time of the dropping of the poor solvent onto the coating film.

Examples of the aromatic hydrocarbon include toluene, benzene, and xylene.

Examples of the halogenated aromatic hydrocarbon include chlorobenzene, dichlorobenzene, and bromobenzene.

Of those aromatic hydrocarbon and halogenated aromatic hydrocarbon, an aromatic hydrocarbon is preferred, and toluene is more preferred.

An environmental temperature in the poor solvent-dropping step is, for example, from 0° C. to 70° C., or for example, from 5° C. to 40° C.

The poor solvent is dropped onto the coating film 14a at any appropriate temperature. When the poor solvent is dropped onto the coating film, the solubility of the perovskite compound varies greatly depending on the kind of the poor solvent and the composition ratio thereof with the good solvent. In one example, however, when the mass ratio of the good solvent to the poor solvent is 1:2, the solubility reduces to about ⅕ of that when the good solvent is used alone, and when the mass ratio is 1:5, the solubility reduces to 1/10 or less of that when the good solvent is used alone.

The boiling point of the poor solvent is, for example, from 30° C. to 200° C., preferably from 80° C. to 150° C.

The temperature of the poor solvent is, for example, from 20° C. to 70° C. In one embodiment, the temperature of the poor solvent is higher than the temperature of the coating film 14a (i.e., the above-mentioned environmental temperature). In this case, the temperature of the poor solvent is, for example, from 45° C. to 100° C., preferably from 45° C. to 85° C., more preferably from 50° C. to 70° C. When the temperature of the poor solvent to be dropped onto the coating film falls within such ranges, precipitation of the microcrystal nuclei of the perovskite compound can be promoted, and excessive growth of the sizes of the microcrystal nuclei can be suppressed.

The dropping amount of the poor solvent is, for example, from 0.01 mol/m² to 0.02 mol/m² per application area of the raw material solution.

In one embodiment, the poor solvent is applied to the coating film 14a by a spin coating method similarly to the coating film-forming step. More specifically, the poor solvent is dropped onto the coating film 14a on the base material 1 while the base material 1 is rotated at a predetermined rotation speed. Thus, the poor solvent is appropriately mixed with the good solvent while being spread by a centrifugal force. Accordingly, the supersaturation degree of the perovskite compound in the coating film can be appropriately increased, and hence the microcrystal nuclei of the perovskite compound can be precipitated at an excellent precipitation rate.

The rotation speed of the base material 1 in the poor solvent-dropping step is, for example, from 1,000 rpm to 6,000 rpm. In one embodiment, the rotation speed of the base material 1 in the poor solvent-dropping step is faster than the rotation speed of the base material 1 in the coating film-forming step. In this case, the rotation speed of the base material 1 is, for example, from 4,000 rpm to 10,000 rpm.

Thus, the microcrystal nuclei of the perovskite compound can be stably precipitated at the above-mentioned precipitation rate. Accordingly, typically, a precursor film containing the microcrystal nuclei of the perovskite compound is prepared from the coating film 14a.

### D. Annealing Step

In an annealing step, the precursor film containing the microcrystal nuclei of the perovskite compound is aggregated and densified. Thus, the perovskite semiconductor film 14 is prepared from the precursor film. In the illustrated example, the perovskite semiconductor film 14 is directly arranged on the electron-transporting layer 13.

An annealing temperature is, for example, from 130° C. to 170° C.

An annealing time is, for example, from 1 minute to 60 minutes, preferably from 5 minutes to 20 minutes.

The perovskite semiconductor film 14 is a light-absorbing layer (photoactive layer), and can perform photoelectric conversion by moving an electron and a hole excited by light absorption.

The perovskite semiconductor film 14 has a perovskite crystal structure. The perovskite semiconductor film 14 contains a perovskite crystal and/or a perovskite complex.

The perovskite semiconductor film 14 has excellent denseness.

The thickness of the perovskite semiconductor film 14 is, for example, from 50 nm to 1,000 nm, preferably from 200 nm to 800 nm. The thickness of the perovskite semiconductor film may be typically measured with a cross-sectional scanning electron microscope (cross-sectional SEM).

In a range measuring 500 nm by 500 nm in a horizontal direction when the surface of the perovskite semiconductor film 14 is subjected to measurement with a scanning electron microscope, the height difference of the surface is preferably 50 nm or less (from −25 nm to +25 nm), more preferably 40 nm or less (from −20 nm to +20 nm).

### E. Production of Photoelectric Conversion Device

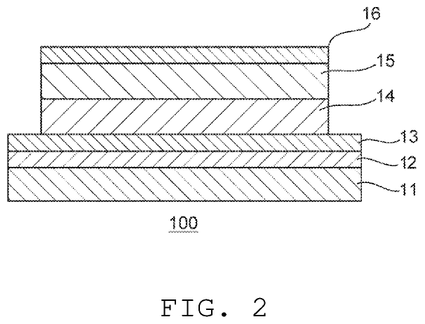

The above-mentioned perovskite semiconductor film 14 may be suitably used for producing a photoelectric conversion device 100. As illustrated in FIG. 2, in one embodiment, the photoelectric conversion device 100 is produced by sequentially preparing a hole-transporting layer 15 and an electrode 16 on the perovskite semiconductor film 14.

The hole-transporting layer 15 is typically prepared by applying a solution of a hole-transporting material to the perovskite semiconductor film 14 and then firing the coating film as required.

The solution of the hole-transporting material is prepared by dissolving the hole-transporting material in any appropriate organic solvent.

The hole-transporting material can receive a hole from the perovskite semiconductor film and transport the hole. Examples of the hole-transporting material include a conductor, a semiconductor, and an organic hole-transporting material. The hole-transporting materials may be used alone or in combination thereof.

Examples of the organic solvent include the above-mentioned poor solvents. Of those, an aromatic hydrocarbon and a halogenated aromatic hydrocarbon are preferred. The organic solvents may be used alone or in combination thereof.

The solution of the hole-transporting material may contain any appropriate additive. Examples of the additive include an oxidizing agent and a basic compound.

Examples of a method of applying the solution of the hole-transporting material include a spin coating method, an inkjet method, a gravure method, and a die coating method. Of those, a spin coating method is preferred.

A firing temperature is, for example, from 30° C. to 120° C., preferably from 50° C. to 90° C.

A firing time is, for example, from 5 minutes to 120 minutes, preferably from 15 minutes to 45 minutes.

Thus, the hole-transporting layer 15 is formed on the perovskite semiconductor film 14. The hole-transporting layer 15 has a function of transporting charge. In the illustrated example, the hole-transporting layer 15 is positioned on the opposite side of the electron-transporting layer 13 with respect to the perovskite semiconductor film 14, and is directly arranged on the perovskite semiconductor film 14. The hole-transporting layer 15 may be arranged on the entirety of the surface of the perovskite semiconductor film 14, or may be arranged only on part of the surface of the perovskite semiconductor film 14.

The thickness of the hole-transporting layer 14 is, for example, from 1 nm to 1,000 nm, preferably from 10 nm to 200 nm.

The electrode 16 is typically prepared by forming a film of a metal material on the hole-transporting layer 15.

Examples of the metal material include gold, silver, copper, aluminum, nickel, indium, and titanium. Of those, gold is preferred. The metal materials may be used alone or in combination thereof.

Examples of a film forming method for the metal material include vacuum deposition and sputtering. Of those, vacuum deposition is preferred.

Thus, the electrode 16 is formed on the hole-transporting layer 15. The electrode 16 has a function of taking charge out of the perovskite semiconductor film 14. In the illustrated example, the electrode 16 is positioned on the opposite side of the perovskite semiconductor film 14 with respect to the hole-transporting layer 15, and is directly arranged on the hole-transporting layer 15. The electrode 16 may be arranged on the entirety of the surface of the hole-transporting layer 15, or may be arranged only on part of the surface of the hole-transporting layer 15.

The thickness of the electrode 16 is adjusted in any appropriate manner so that a sheet resistance per unit area may be less than 15 Ω/mm².

Thus, the photoelectric conversion device 100 having the structure “electrode 16/hole-transporting layer 15/perovskite semiconductor film 14/electron-transporting layer 13/transparent electrode film 12/base material body 11” is produced.

### EXAMPLES

The present disclosure is specifically described below by way of Examples. However, the present disclosure is not limited to these Examples.

### Examples 1 and 2, and Comparative Example 1

A glass substrate (base material body) having arranged thereon an indium tin oxide film (ITO film) having a thickness of 150 nm was prepared. Next, the glass substrate having arranged thereon the ITO film (hereinafter referred to as “glass substrate with ITO”) was subjected to ultrasonic cleaning, and was then dried.

After that, a colloidal aqueous solution of SnO₂ (manufactured by Alfa Aesar) was diluted to ½ with distilled water, and was applied in an amount of 320 μL/sheet onto the glass substrate with ITO by spin coating. Specifically, the glass substrate with ITO was rotated at 2,000 rpm for 30 seconds, and then the number of revolutions was reduced to 0 rpm at a slope of 2 seconds. After that, the coating film was annealed at 150° C. for 30 minutes. Thus, an electron-transporting layer having a thickness of 40 nm was formed. Thus, a laminated base material having the structure “electron-transporting layer/ITO film/glass substrate” was obtained.

In addition, a mixture containing Cₛ, formamidine (FA), methylamine (MA), PbI, and Br at 0.05:0.80:0.15:2.68:0.32 (molar ratio) was dissolved in a good solvent shown in Table 1 to prepare a raw material solution having a Pb concentration of 1.3 mol/L. The transition of a supersaturation degree S and the transition of the content ratio C of the good solvent in a coating film formed by applying the raw material solution onto the electron-transporting layer by spin coating under the following conditions were calculated in advance by computer simulation. Thus, the maximum supersaturation degree Sₘₐₓ of the coating film that is achievable without dropping a poor solvent onto the coating film is calculated.

### <Spin Coating Conditions>

Temperature: 35° C.
Dropping amount: 0.9 L/sheet to 1.0 L/sheet
Rotation speed of laminated substrate: 5,000 rpm
Coating film thickness when rotation is stable: about 2 μm

Next, the laminated base material was placed on the stage of a spin coater, and the coating film was formed on the electron-transporting layer under the above-mentioned spin coating conditions.

Next, at a timing (poor solvent-dropping time) when each of the ratio “supersaturation degree S/maximum supersaturation degree Sₘₐₓ” and the ratio “content ratio C of the good solvent in the coating film/content ratio Cₛ of the good solvent in the raw material solution” became a value shown in Table 1, a poor solvent shown in Table 1, which had been heated to 65° C., was dropped onto the coating film. The dropping amount of the poor solvent was 0.9 μL/sheet. The maximum value of a crystal precipitation rate (crystal precipitation rate MAX) and the average primary particle diameter of microcrystal nuclei (average crystal nucleus diameter) at the time of the dropping of the poor solvent were calculated by computer simulation on the basis of solubility curve data determined by experiments under the respective conditions. The results are shown in Table 1.

The rotation of the laminated substrate was maintained until 20 seconds passed from the completion of the dropping of the poor solvent. After that, the rotation of the laminated substrate was stopped. Thus, a precursor film was formed on the electron-transporting layer. Next, the resultant precursor film was annealed at 150° C. for 10 minutes to form each perovskite semiconductor film having a thickness of 500 nm.

### Examples 3 and 4, and Comparative Example 2

Perovskite semiconductor films were each formed in the same manner as in Example 1 except that the good solvent was changed from dimethylformamide (DMF) to dimethyl sulfoxide (DMSO).

### Example 5, and Comparative Examples 3 and 4

Perovskite semiconductor films were each formed in the same manner as in Example 3 except that the poor solvent was changed from toluene to chlorobenzene (PhCl).

### <Evaluation of Perovskite Semiconductor Film>

The performance of each of the perovskite semiconductor films obtained in Examples and Comparative Examples was evaluated by a cross-sectional SEM image of a perovskite film produced under similar conditions and conversion efficiency measured by assembling the film into a battery. The relative evaluation of the conversion efficiency is roughly as described below. The results are shown in Table 1.
⊚: 0.9 or more and 1 or less
o: 0.8 or more and less than 0.9
Δ: 0.5 or more and less than 0.8
x: Less than 0.5

TABLE 1

| | Example | Example | Comparative |
|---|---|---|---|
| No. | 1 | 2 | Exampl |

| | |
|---|---|
| Good solvent | DMF |
| Poor solvent | Toluene |

| | | | | |
|---|---|---|---|---|
| Poor solvent-dropping time | S/Sₘₐₓ × 100 | 88 | 100 | 60 |
| | C/C_{S} × 100 | 35 | 15 | 50 |
| Average crystal nucleus diameter | [nm] | 3.1 | 3.3 | 3.5 |
| Crystal precipitation rate MAX | [kg/m²s] | 0.095 | 0.042 | 0.011 |

| Evaluation | ⊚ | Δ | X |
|---|---|---|---|
| | | | Comparative |
| | | Example | Example |
| No. | Example 3 | 4 | 2 |

| | |
|---|---|
| Good solvent | DMSO |
| Poor solvent | Toluene |

| | | | | |
|---|---|---|---|---|
| Poor solvent-dropping time | S/Sₘₐₓ × 100 | 95 | 100 | 75 |
| | C/C_{S} × 100 | 70 | 50 | 90 |
| Average crystal nucleus diameter | [nm] | 3.3 | 3.3 | 3.5 |
| Crystal precipitation rate MAX | [kg/m²s] | 0.09 | 0.068 | 0.03 |

| | | | |
|---|---|---|---|
| Evaluation | ⊚ | ◯ | X |

| | | | Comparative | Comparative |
|---|---|---|---|---|
| | | | Example | Example |
| No. | | Example 5 | 3 | 4 |
| Good solvent | | DMSO | | |
| Poor solvent | | PhCl | | |
| Poor solvent-dropping time | S/Sₘₐₓ × 100 | 100 | 80 | 100 |
| | C/C_{S} × 100 | 20 | 60 | 8 |
| Average crystal nucleus diameter | [nm] | 3.4 | 3.6 | 3.4 |
| Crystal precipitation rate MAX | [kg/m²s] | 0.029 | 0.004 | 0.009 |

| | | | |
|---|---|---|---|
| Evaluation | ◯ | X | X |

As is clear from Table 1, it is found that when the ratio “supersaturation degree S of the coating film/maximum supersaturation degree Sₘₐₓ exceeds 80% (i.e., maximum supersaturation degree Sₘₐₓ×0.80<supersaturation degree S of the coating film is satisfied), and the ratio “content ratio C of the good solvent in the coating film/content ratio Cₛ of the good solvent in the raw material solution” is 15% or more (i.e., content ratio Cₛ of the good solvent in the raw material solution×0.15≤content ratio C of the good solvent in the coating film is satisfied), the crystal precipitation rate at the time of the dropping of the poor solvent can be improved. When the crystal precipitation rate in the coating film is improved as described above, microcrystal nuclei can be sufficiently produced, and hence the densification of the perovskite semiconductor film can be achieved.

The method of producing a perovskite semiconductor film according to the embodiment of the present disclosure enables the production of a perovskite semiconductor film that may be utilized in various industrial products. The perovskite semiconductor film may be suitably used particularly as the perovskite semiconductor film of, for example, a solar cell or an electroluminescence (EL) device.

What is claimed is:

1. A method of producing a perovskite semiconductor film, comprising the steps of:
forming a coating film from a raw material solution, which is obtained by dissolving a perovskite compound in a good solvent, under a predetermined temperature; and
dropping a poor solvent onto the coating film when a supersaturation degree S of the coating film satisfies the following formula (1) and a content ratio C of the good solvent in the coating film satisfies the following formula (2):
$${S}_{max} \times 0.8 < S \qquad ( 1 )$$
in the formula (1), Sₘₐₓ represents a maximum supersaturation degree of the coating film that is achievable without dropping the poor solvent onto the coating film at the predetermined temperature; and
$${C}_{s} \times 0.15 \leq C \qquad ( 2 )$$
in the formula (2), Cₛ represents a content ratio of the good solvent in the raw material solution.

2. The method of producing a perovskite semiconductor film according to claim 1, wherein the poor solvent is dropped onto the coating film when the supersaturation degree S of the coating film satisfies the following formula (3):
$${S}_{max} \times 0.9 \leq S \leq {S}_{max} \times 0.98 \qquad ( 3 )$$
in the formula (3), Sₘₐₓ represents the maximum supersaturation degree of the coating film that is achievable without dropping the poor solvent onto the coating film at the predetermined temperature.

3. The method of producing a perovskite semiconductor film according to claim 1, wherein the poor solvent is dropped onto the coating film when the content ratio C of the good solvent in the coating film satisfies the following formula (4):
$${C}_{s} \times 0.18 \leq C \leq {C}_{s} \times 0.6 \qquad ( 4 )$$
in the formula (4), Cₛ represents the content ratio of the good solvent in the raw material solution.

4. The method of producing a perovskite semiconductor film according to claim 1, wherein the perovskite compound includes a compound represented by the following general formula (I):
ABX₃ (I)
in the general formula (I), A represents an organic ammonium and/or an alkali metal cation, B represents a divalent metal cation, and X represents a halide and/or an anion source.

5. The method of producing a perovskite semiconductor film according to claim 1, wherein the good solvent includes an aprotic polar solvent.

6. The method of producing a perovskite semiconductor film according to claim 1, wherein the poor solvent includes an aromatic hydrocarbon.
